(19) United States
(12) Patent Application Publication
(10) Pub. No.: US 2024/0332400 A1
(43) Pub. Date: Oct. 3, 2024

(54) SEMICONDUCTOR STRUCTURE AND FORMING METHOD THEREOF

(71) Applicant: Semiconductor Manufacturing International (Shanghai) Corporation, Shanghai (CN)

(72) Inventors: Bo SU, Shanghai (CN); Hansu OH, Shanghai (CN)

(73) Assignee: Semiconductor Manufacturing International (Shanghai) Corporation, Shanghai (CN)

(21) Appl. No.: 18/615,032

(22) Filed: Mar. 25, 2024

(30) Foreign Application Priority Data
Mar. 28, 2023 (CN) 202310317113.3

(51) Int. Cl. H01L 29/66; H01L 29/06; H01L 29/423; H01L 29/775; H01L 29/786

(52) U.S. Cl. CPC H01L 29/66553; H01L 29/0673; H01L 29/42392; H01L 29/66439; H01L 29/775; H01L 29/78696

(57) ABSTRACT

A semiconductor structure includes: a channel protrusion structure, suspended on a base, including channel layers arranged at intervals along a longitudinal direction; a gate structure, spanning the channel protrusion structure and covering part of a top and part of a side wall of the channel protrusion structure, surrounding and covering the channel layers, the gate structure located between adjacent channel layers in the longitudinal direction and between adjacent channel layers and the base serving as an inner gate structure, and the inner gate structure and the adjacent channel layers, and/or, the inner gate structure, the adjacent channel layers and the base forming an inner trench; an inner spacer, located in the inner trench; and a source/drain doped layer, located on the base and connected to two ends of the channel layer, the source/drain doped layer and the inner spacer having a gap therebetween used as an air spacer.

### RELATED APPLICATIONS

The present application claims priority to Chinese Patent Application No. 202310317113.3, filed on Mar. 28, 2023, the entire content of which is incorporated herein by reference.

### TECHNICAL FIELD

Embodiments and implementations of the present disclosure relate to the field of semiconductor manufacturing, and in particular to a semiconductor structure and a forming method thereof.

### BACKGROUND

With the rapid development of the semiconductor integrated circuit (IC) industry, semiconductor technology continues to move toward smaller process nodes under the driving force of Moore's Law, making the integrated circuits develop toward a direction of smaller size, higher circuit precision and higher circuit complexity.

In order to adapt to the scale-down of the size of the device, semiconductor processes have gradually begun to transition from planar transistors to three-dimensional transistors with higher efficacy, such as gate-all-around (GAA) transistors. In a gate-all-around transistor, the gate surrounds the area where the channel is located from all sides. Compared with the planar transistor, the gate of the gate-all-around transistor has better control over the channel and can better suppress the short-channel effect.

However, the performance of the gate-all-around transistors still needs to be improved.

### SUMMARY

The problem to be addressed by embodiments and implementations of the present disclosure is to provide a semiconductor structure and a forming method thereof to improve the performance of the semiconductor structure.

To address the above problem, the present disclosure provides a semiconductor structure. In one form, a semiconductor structure includes: a base; a channel protrusion structure, suspended on the base, the channel protrusion structure including one or more channel layers arranged at intervals along a longitudinal direction; a gate structure, spanning the channel protrusion structure and covering part of a top and part of a side wall of the channel protrusion structure, the gate structure further surrounding and covering the channel layers, the gate structure located between the adjacent channel layers in the longitudinal direction and between the adjacent channel layers and the base serving as an inner gate structure, and the inner gate structure and the adjacent channel layers, and/or, the inner gate structure, the adjacent channel layers and the base forming an inner trench; an inner spacer, located in the inner trench; and a source/drain doped layer, located on the base on two sides of the gate structure and connected to two ends of the channel layer, the source/drain doped layer and the inner spacer having a gap therebetween, and the gap being used as an air spacer.

In some implementations, the inner spacer fills part of space in the inner trench; and the source/drain doped layer seals the inner trench and forms the gap with the inner spacer.

In some implementations, the inner spacer conformally covers an inner wall of the inner trench.

In some implementations, along a direction perpendicular to a side wall of the inner gate structure, the inner gate structure between the inner trenches has a smaller width near a middle position than a top width and a bottom width, so that the inner trench has a larger lateral depth near the middle position than a lateral depth at a position near the channel layer.

In some implementations, a side wall of the inner trench facing the inner gate structure is 2-shaped or bowl-shaped.

In some implementations, the inner spacer includes a first inner spacer covering the inner wall of the inner trench, and a second inner spacer covering the first inner spacer, and there is an etch selectivity between the second inner spacer and the first inner spacer.

In some implementations, a thickness of the first inner spacer is 0.5 nm to 50 nm.

In some implementations, a material of the inner spacer includes at least one of silicon oxide, silicon nitride, silicon oxynitride, silicon oxycarbide or silicon oxycarbonitride.

In some implementations, a shape of the gap includes at least one of crescent, ellipsoidal, hemispherical or irregular shapes.

In some implementations, the base includes a substrate and a bottom fin protruding from the substrate; the channel protrusion structure is suspended on the bottom fin; and the semiconductor structure further includes: a first isolation layer, located on the substrate on a side of the bottom fin, the first isolation layer covering a side wall of the bottom fin.

The disclosure further provides a forming method of a semiconductor structure. In one form, a method includes: providing a base, one or more channel stacks sequentially stacked along a longitudinal direction being formed on the base, and each channel stack including a sacrificial layer and a channel layer located on the sacrificial layer; forming a gate structure spanning the channel stack, the gate structure covering part of a top and part of a side wall of the channel stack; removing the channel stack on two sides of the gate structure; laterally removing, after removing the channel stack on the two sides of the gate structure, part of a width of the sacrificial layer along a direction perpendicular to a side wall of the gate structure to form an inner trench between the channel layers and/or between the channel layers and the base; forming an inner spacer in the inner trench; and forming a source/drain doped layer connected to two ends of the channel layer on the base on the two sides of the gate structure, the source/drain doped layer and the inner spacer having a gap therebetween, and the gap being used as an air spacer.

In some implementations, the step of forming the inner spacer in the inner trench includes: forming an inner spacer material layer covering the side wall and the top of the gate structure, the ends of the channel stack and the base on the sides of the gate structure, the inner spacer material layer further filling the inner trench; and removing the inner spacer material layer on the side wall and the top of the gate structure, the ends of the channel stack and the base on the sides of the gate structure, and removing part of the inner spacer material layer located in the inner trench, such that the inner spacer material layer fills part of space in the inner trench and the remaining inner spacer material layer serves as the inner spacer. In the step of forming the source/drain doped layer, the source/drain doped layer seals the inner trench and forms the gap with the inner spacer.

In some implementations, a process of forming the inner spacer material layer includes an atomic layer deposition process.

In some implementations, in the step of removing part of the inner spacer material layer located in the inner trench, the inner spacer material layer conformally covers an inner wall of the inner trench.

In some implementations, the step of forming the inner spacer material layer includes: forming a first inner spacer material layer on the side wall and the top of the gate structure, the ends of the channel stack and the base on the sides of the gate structure, the first inner spacer material layer further covering an inner wall of the inner trench; and forming a second inner spacer material layer covering the first inner spacer material layer, the second inner spacer material layer further filling the inner trench, the first inner spacer material layer and the second inner spacer material layer forming the inner spacer material layer, and there being an etch selectivity between the second inner spacer material layer and the first inner spacer material layer. The step of removing the inner spacer material layer on the side wall and the top of the gate structure, the ends of the channel stack and the base on the sides of the gate structure, and removing part of the inner spacer material layer located in the inner trench includes: removing the second inner spacer material layer on the side wall and the top of the gate structure, the ends of the channel stack and the base on the sides of the gate structure, and removing part of the second inner spacer material layer located in the inner trench, such that the second inner spacer material layer fills part of the space in the inner trench; and removing, after the second inner spacer material layer fills part of the space in the inner trench, the first inner spacer material layer on the side wall and the top of the gate structure, the ends of the channel stack and the base on the sides of the gate structure, the remaining first inner spacer material layer and the second inner spacer material layer forming the inner spacer.

In some implementations, before forming the source/drain doped layer, the method further includes: precleaning the base on the two sides of the gate structure and the ends of the channel stack, and during the precleaning process, removing the first inner spacer material layer on the side wall and the top of the gate structure, the ends of the channel stack and the base on the sides of the gate structure.

In some implementations, a process of removing the second inner spacer material layer on the side wall and the top of the gate structure, the ends of the channel stack and the base on the sides of the gate structure includes an anisotropic plasma etching process, and a process of removing part of the second inner spacer material layer located in the inner trench includes an isotropic plasma etching process. A process of removing the first inner spacer material layer on the side wall and the top of the gate structure, the ends of the channel stack and the base on the sides of the gate structure includes one or two of a wet etching process or a chemical vapor etching process.

In some implementations, in the process of removing part of the second inner spacer material layer located in the inner trench, the etch selectivity between the second inner spacer material layer and the first inner spacer material layer is larger than 80. In the process of removing the first inner spacer material layer on the side wall and the top of the gate structure, the ends of the channel stack and the base on the sides of the gate structure, the etch selectivity between the first inner spacer material layer and the second inner spacer material layer is larger than 100.

In some implementations, in the step of laterally removing part of the width of the sacrificial layer along the direction perpendicular to the side wall of the gate structure to form the inner trench between the channel layers and/or between the channel layers and the base, the remaining sacrificial layer between the inner trenches has a smaller width near a middle position than a top width and a bottom width, so that the inner trench has a larger lateral depth near the middle position than a lateral depth at a position near the channel layer.

In some implementations, a process of laterally removing part of the width of the sacrificial layer includes: one or two of a chemical vapor etching process and a plasma etching process.

Compared with the prior art, technical solutions provided by embodiments and implementations of the present disclosure have at least the following advantages:

In forms of a semiconductor structure, the inner gate structure and the adjacent channel layers, and/or, the inner gate structure, the adjacent channel layers and the base form the inner trench, the inner spacer is located in the inner trench, the source/drain doped layer is located on the base on the two sides of the gate structure and connected to the two ends of the channel layer, the source/drain doped layer and the inner spacer have the gap therebetween, and the gap is used as the air spacer. Since the air has a smaller dielectric constant than the dielectric material, the parasitic capacitance of the semiconductor device is reduced, thereby improving the alternating current (AC) performance of the semiconductor device and further improving the performance of the semiconductor structure.

In forms of a forming method of a semiconductor structure, the inner trench is formed between the channel layers, and/or, between the channel layers and the base; the inner spacer is formed in the inner trench; and the source/drain doped layer connected to the two ends of the channel layer is formed on the base on the two sides of the gate structure, the source/drain doped layer and the inner spacer having the gap therebetween, and the gap being used as the air spacer. Since the air has a smaller dielectric constant than the dielectric material, the parasitic capacitance of the semiconductor device formed subsequently is reduced, thereby improving the alternating current (AC) performance of the semiconductor device formed subsequently and further improving the performance of the semiconductor structure.

### BRIEF DESCRIPTION OF THE DRAWINGS

FIG. 1 to FIG. 3 are schematic structural views of one form of a semiconductor structure; and

FIG. 4 to FIG. 26 are schematic structural views corresponding to steps of one form of a forming method of a semiconductor structure.

### DETAILED DESCRIPTION

As can be known from the BACKGROUND, in order to adapt to the scale-down of the size of the device, semiconductor processes have gradually begun to transition from planar transistors to three-dimensional transistors with higher efficacy. Especially after the transition to the gate-all-around transistors with smaller size, how to reduce the parasitic capacitance of the gate-all-around transistors has become an urgent problem to be solved.

To address the above technical problems, the present disclosure provides a semiconductor structure. In one form, a semiconductor structure includes: a base; a channel protrusion structure, suspended on the base, the channel protrusion structure including one or more channel layers arranged at intervals along a longitudinal direction; a gate structure, spanning the channel protrusion structure and covering part of a top and part of a side wall of the channel protrusion structure, the gate structure further surrounding and covering the channel layers, the gate structure located between the adjacent channel layers in the longitudinal direction and between the adjacent channel layers and the base serving as an inner gate structure, and the inner gate structure and the adjacent channel layers, and/or, the inner gate structure, the adjacent channel layers and the base forming an inner trench; an inner spacer, located in the inner trench; and a source/drain doped layer, located on the base on two sides of the gate structure and connected to two ends of the channel layer, the source/drain doped layer and the inner spacer having a gap therebetween, and the gap being used as an air spacer.

A semiconductor structure may include: the inner trench, formed by the inner gate structure and the adjacent channel layers, and/or, the inner gate structure, the adjacent channel layers and the base; the inner spacer, located in the inner trench; and the source/drain doped layer, located on the base on the two sides of the gate structure and connected to the two ends of the channel layer, the source/drain doped layer and the inner spacer having the gap therebetween, and the gap being used as the air spacer. Since the air has a smaller dielectric constant than the dielectric material, the parasitic capacitance of the semiconductor device is reduced, thereby improving the alternating current performance of the semiconductor device and further improving the performance of the semiconductor structure.

To make the foregoing objects, features, and advantages of embodiments and implementations of the present disclosure more apparent and easier to understand, specific embodiments and implementations of the disclosure are described in detail below with reference to the accompanying drawings.

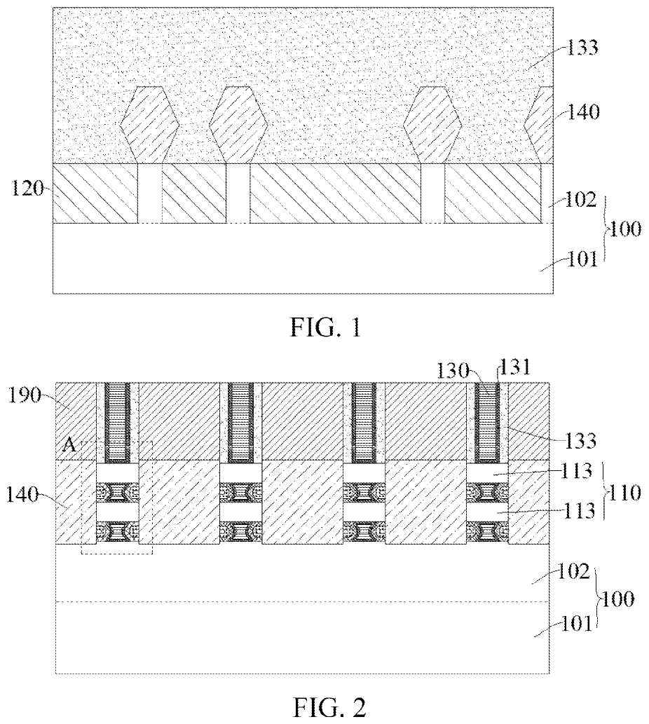

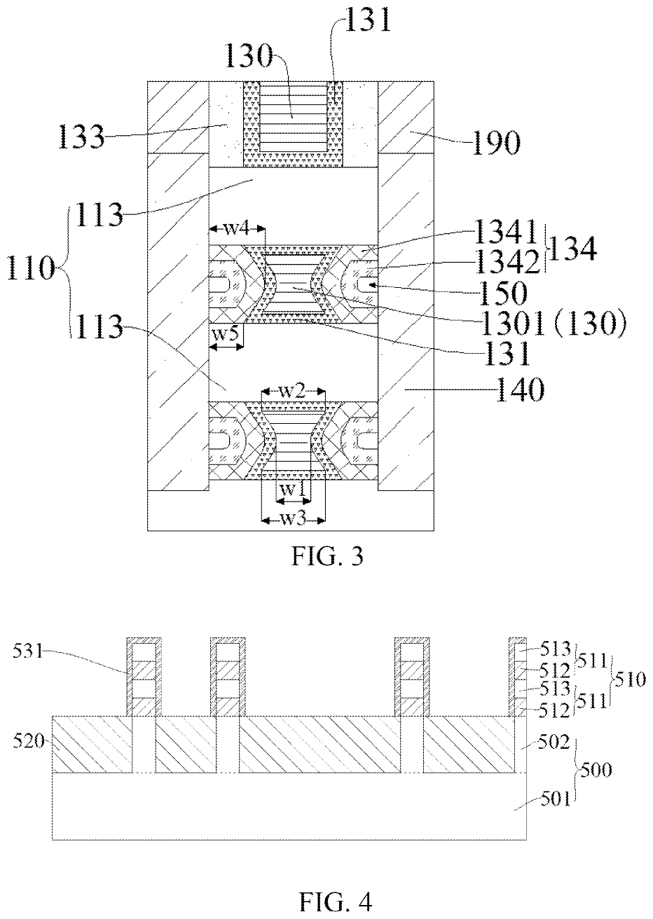

FIG. 1 to FIG. 3 are schematic structural views of one form of a semiconductor structure. FIG. 1 is a cross-sectional view at a side of a gate structure 130 along an extending direction of the gate structure 130. FIG. 2 is a cross-sectional view at a channel protrusion structure 110 along an extending direction of the channel protrusion structure 110, with the cross-sectional line near a middle position of the channel protrusion structure 110. FIG. 3 is a partial enlarged view of A in FIG. 2.

In some implementations, the semiconductor structure includes: a base 100; a channel protrusion structure 110, suspended on the base 100, the channel protrusion structure 110 including one or more channel layers 113 arranged at intervals along a longitudinal direction; a gate structure 130, spanning the channel protrusion structure 110 and covering part of a top and part of a side wall of the channel protrusion structure 110, the gate structure 130 further surrounding and covering the channel layers 113, the gate structure 130 located between the adjacent channel layers 113 in the longitudinal direction and between the adjacent channel layers 113 and the base 100 serving as an inner gate structure 1301, and the inner gate structure 1301 and the adjacent channel layers 113, and/or, the inner gate structure 1301, the adjacent channel layers 113 and the base 100 forming an inner trench (not shown); an inner spacer 134, located in the inner trench; and a source/drain doped layer 140, located on the base 100 on two sides of the gate structure 130 and connected to two ends of the channel layer 113, the source/drain doped layer 140 and the inner spacer 134 having a gap 150 therebetween, and the gap 150 being used as an air spacer.

The base 100 is used for providing a process platform for the forming process of the semiconductor structure.

In some implementations, the base 100 is used for forming a gate-all-around transistor.

In some implementations, the base 100 includes a substrate 101 and a bottom fin 102 protruding from the substrate 101. It should be noted that the substrate 101 is a silicon substrate. In other implementations, a material of the substrate may also be another material such as germanium, silicon-germanium, silicon carbide, gallium arsenide, indium-gallium or the like. The substrate may also be another type of substrate such as a silicon on insulator substrate, a germanium on insulator substrate or the like.

As an example, the bottom fin 102 and the substrate 101 are an integrated structure.

Accordingly, the channel protrusion structure 110 is suspended on the bottom fin 102.

The channel protrusion structure 110 includes one or more channel layers 113 arranged at intervals along the longitudinal direction. Here, the longitudinal direction refers to the normal direction of the top surface of the substrate 101.

The channel layer 113 is used as a conductive channel of the gate-all-around transistor.

A material of the channel layer 113 may be at least one of silicon, germanium, silicon-germanium, silicon carbide, gallium nitride, gallium arsenide or indium-gallium. In some implementations, the material of the channel layer 113 is silicon.

As shown in FIG. 1, in some implementations, the semiconductor structure further includes: a first isolation layer 120, located on the substrate 101 on a side of the bottom fin 102, the first isolation layer 120 covering a side wall of the bottom fin 102.

The first isolation layer 120 is used for realizing electrical isolation between the adjacent bottom fins 102, and may further isolate the substrate 101 and the gate structure 130.

In some implementations, the first isolation layer 120 is a shallow trench isolation (STI).

A material of the first isolation layer 120 includes at least one of silicon oxide, silicon nitride or silicon oxynitride.

In some implementations, the semiconductor structure further includes: a gate dielectric layer 131, located between the channel protrusion structure 110 and the gate structure 130.

The gate dielectric layer 131 is used for isolating the gate structure 130 and the channel protrusion structure 110.

A material of the gate dielectric layer 131 includes at least one of HfO₂, ZrO₂, HfSiO, HfSiON, HfTaO, HfTiO, HfZrO, Al₂O₃, SiO₂ or La₂O₃.

The gate structure 130 is a device gate structure used for forming the gate-all-around transistor with the channel protrusion structure 110 and the source/drain doped layer 140. In some implementations, the gate structure 130 is a metal gate structure.

A material of the gate structure 130 includes at least one of TiN, TaN, Ta, Ti, TiAl, W, Al, TiSiN or TiAIC. The gate structure 130 includes a work function layer and an electrode layer covering the work function layer, and may only include the work function layer.

Accordingly, the gate dielectric layer 131 includes a high K gate dielectric layer. A material of the high k gate dielectric layer is a high k dielectric material. The high k dielectric material is a dielectric material with a relative dielectric constant greater than a relative dielectric constant of the silicon oxide. Specifically, the material of the high k gate dielectric layer may be selected from HfO₂, ZrO₂, HfSiO, HfSiON, HfTaO, HfTIO, HfZrO, Al₂O₃ or the like. As an example, the material of the high k gate dielectric layer is HfO₂.

In other implementations, the gate structure may also be a poly gate structure.

In some implementations, the semiconductor structure further includes: a spacer structure 133, located on the side wall of the gate structure 130.

The spacer structure 133 is used for protecting the side wall of the gate structure 130 during the forming process of the semiconductor structure.

It should be noted that the spacer structure 133 may be a single-layer structure or a laminate structure, and a material of the spacer structure 133 includes at least one of silicon oxide, silicon nitride, silicon carbide, silicon carbonitride, silicon oxycarbonitride, silicon oxynitride, boron nitride or boron carbonitride.

In some implementations, along a direction perpendicular to a side wall of the inner gate structure 1301, a width of the inner gate structure 1301 is smaller than a length of the channel layer 113, so the inner gate structure 1301 and the adjacent channel layers 113, and/or, the inner gate structure 1301, the adjacent channel layers 113 and the base 100 form the inner trench (not shown). The inner trench provides a spatial position for the formation of the inner spacer 134.

In some implementations, along the direction perpendicular to the side wall of the inner gate structure 1301, the inner gate structure 1301 between the inner trenches has a smaller width w1 near a middle position than a top width w2 and a bottom width w3, so that the inner trench has a larger lateral depth w4 near the middle position than a lateral depth w5 at a position near the channel layer 113. Here, the lateral depth refers to the depth of the inner trench along the direction perpendicular to the side wall of the inner gate structure 1301. The middle position refers to the middle position of the inner gate structure 1301 along its height direction.

The inner gate structure 1301 between the inner trenches has a smaller width near the middle position than the top width and the bottom width, that is, the side wall of the inner gate structure 1301 is recessed to the inside.

The lateral depth of the inner trench near the middle position is larger than the lateral depth at the position near the channel layer 113, which, as compared with the solution in which the lateral depth at the position near the channel layer 113 is equal to the lateral depth near the middle position, increases the inner space of the inner trench near the middle position, making it easy to leave a gap between the inner spacer 134 and the source/drain doped layer 140. Here, the lateral depth refers to the depth of the inner trench along the direction perpendicular to the side wall of the gate structure 130.

Specifically, a side wall of the inner trench facing the inner gate structure 1301 is Σ-shaped or bowl-shaped. That is, the side wall of the inner trench has a corner angle facing the inner gate structure 1301, and the corner angle includes a sharp corner or a round corner.

The side wall of the inner trench facing the inner gate structure 1301 is 2-shaped or bowl-shaped, which helps in reducing the difficulty of the process of forming the inner trench having the lateral depth near the middle position larger than the lateral depth at the position near the channel layer 113, and is easy to achieve in the process.

The inner spacer 134 is used for realizing isolation between the source/drain doped layer 140 and the inner gate structure 1301.

Specifically, a material of the inner spacer 134 includes at least one of silicon oxide, silicon nitride, silicon oxynitride, silicon oxycarbide or silicon oxycarbonitride.

In some implementations, the inner spacer 134 fills part of space in the inner trench; and accordingly, the source/drain doped layer 140 seals the inner trench and forms the gap 150 with the inner spacer 134.

The inner spacer 134 only fills part of the space in the inner trench, thereby providing the space required for forming the gap 150, making it easy to form the gap 150 between the inner spacer 134 and the source/drain doped layer 140, and reducing the difficulty of the process of forming the gap 150.

Specifically, the inner spacer 134 conformally covers an inner wall of the inner trench.

The inner spacer 134 conformally covers the inner wall of the inner trench, which helps in increasing the space in the inner trench that is not filled by the inner spacer 134 and further helps in increasing the volume of the gap 150 between the inner spacer 134 and the source/drain doped layer 140, making a better effect of reducing the parasitic capacitance of the semiconductor device.

Moreover, this helps in improving the covering power of the inner spacer 134 on the surface of the channel layer 113 in the inner trench, thereby reducing the probability of growth of the source/drain doped layer 140 on the basis of the surface of the channel layer 113 in the inner trench, and further reducing the probability of the source/drain doped layer 140 filling the inside of the inner trench. Accordingly, the source/drain doped layer 140 can easily seal the inner trench at the opening of the inner trench so as to form the gap 150 with larger space.

In addition, this also helps in improving the covering power of the inner spacer 134 on the inner wall of the inner trench, and accordingly improves the completeness of the inner spacer 134, thereby reducing the probability of damage to the source/drain doped layer 140. Specifically, in the forming process of the semiconductor structure, the position of the inner gate structure 1301 is firstly occupied by the sacrificial layer, and after the sacrificial layer is removed, the inner gate structure 1301 is formed at the position of the sacrificial layer, so that the covering power of the inner spacer 134 on the inner wall of the inner trench is improved and the probability of exposing the side wall of the sacrificial layer by the inner spacer 134 is reduced, thereby reducing the probability of damage to the source/drain doped layer 140 caused during the removal of the sacrificial layer via the notch in the inner spacer 134.

It should be noted that along the direction perpendicular to the side wall of the inner gate structure 1301, the inner gate structure 1301 between the inner trenches has the smaller width near the middle position than the top width and the bottom width, so that the inner trench has the larger lateral depth near the middle position than the lateral depth at the position near the channel layer 113. Therefore, based on the size characteristics or morphology characteristics of the inner trench, the inner spacer 134 conformally covers the inner wall of the inner trench, so the inner spacer 134 can easily fill part of the space in the inner trench.

In some implementations, the inner spacer 134 includes a first inner spacer 1341 covering the inner wall of the inner trench, and a second inner spacer 1342 covering the first inner spacer 1341, and there is an etch selectivity between the second inner spacer 1342 and the first inner spacer 1341.

There is an etch selectivity between the second inner spacer 1342 and the first inner spacer 1341, so that in the process of forming the inner spacer 134, the first inner spacer 1341 may serve as a barrier layer, which helps in reducing the probability of damage to other components.

Specifically, in the process of forming the inner spacer 134, the inner spacer material layer used for forming the inner spacer 134 often also covers the side wall and the top of the gate structure 130, the ends of the channel layer 113 and the base 100 on the sides of the gate structure 130. In this case, when removing a part of the second inner spacer material layer corresponding to the second inner spacer 1342, by using the first inner spacer material layer corresponding to the first inner spacer 1341 as the barrier layer, the second inner spacer material layer on the side wall and the top of the gate structure 130, the ends of the channel layer 113 and the base 100 on the sides of the gate structure 130 may be removed, and part of the second inner spacer material layer in the inner trench may be removed, thereby reducing the probability of damage to other components (e.g., the spacer structure 133, the gate structure 130, the channel layer 113 or the base 100).

It should be noted that a thickness of the first inner spacer 1341 should not be too large or too small. If the thickness of the first inner spacer 1341 is too large, the first inner spacer 1341 may easily occupy too much space in the inner trench, and accordingly, the inner spacer 134 may fill too much space in the inner trench 515, making the volume of the gap 150 between the source/drain doped layer 140 and the inner spacer 134 too small. If the thickness of the first inner spacer 1341 is too small, the first inner spacer 1341 may be ineffective as the barrier layer, and accordingly, may be ineffective in reducing damage to other components. Therefore, the thickness of the first inner spacer 1341 is 0.5 nm to 50 nm.

As an example, a material of the first inner spacer 1341 is silicon oxide, and a material of the second inner spacer 1342 is silicon nitride. There is a large etch selectivity between silicon nitride and silicon oxide. Moreover, when the material of the first inner spacer 1341 is silicon oxide, it is easy to remove part of the first inner spacer material layer corresponding to the first inner spacer 1341 before forming the source/drain doped layer 140.

The source/drain doped layer 140 is used as a source or drain of the gate-all-around transistor. When the gate-all-around transistor works, the source/drain doped layer 140 is used for providing a carrier source.

The inner gate structure 1301 and the adjacent channel layers 113, and/or, the inner gate structure 1301, the adjacent channel layers 113 and the base 100 form the inner trench, the inner spacer 134 is located in the inner trench, the source/drain doped layer 140 is located on the base 100 on the two sides of the gate structure 130 and connected to the two ends of the channel layer 113, the source/drain doped layer 140 and inner spacer 134 have the gap 150 therebetween, and the gap 150 air spacer is used as the air spacer. Since the air has a smaller dielectric constant than the dielectric material, the parasitic capacitance of the semiconductor device is reduced, thereby improving the alternating current performance of the semiconductor device and further improving the performance of the semiconductor structure.

Moreover, since the parasitic capacitance of the semiconductor device mainly comes from the parasitic capacitance generated between the gate structure 130 and the source/drain doped layer 140, the air spacer is formed between the source/drain doped layer 140 and the inner spacer 134, which is more effective in reducing the parasitic capacitance of the semiconductor device.

It should be noted that the specific shape of the gap 150 is determined by the process and process parameters for forming the source/drain doped layer 140, and the shape of the inner spacer 134 occupying the space in the inner trench. As an example, the shape of the gap 150 includes at least one of crescent, ellipsoidal, hemispherical or irregular shapes. In other implementations, the shape of the gap may also be other shapes.

As shown in FIG. 2, in some implementations, the semiconductor structure further includes: an interlayer dielectric layer (ILD) 190, located on the first isolation layer 120 on the sides of the gate structure 130 and covering the source/drain doped layer 140. For the specific description of the interlayer dielectric layer 190, details will not be repeated here.

Accordingly, the disclosure further provides a forming method of a semiconductor structure. FIG. 4 to FIG. 26 are schematic structural views corresponding to steps of a forming method of a semiconductor structure according to an embodiment of the disclosure.

Referring to FIG. 4, a base 500 is provided. One or more channel stacks 511 sequentially stacked along a longitudinal direction are formed on the base 500, and each channel stack including a sacrificial layer 512 and a channel layer 513 located on the sacrificial layer.

The base 500 provides a process platform for the subsequent process.

In some implementations, the base 500 is used for forming a gate-all-around transistor.

In some implementations, in the step of providing the base 500, the base 500 further includes a substrate 501 and a bottom fin 502 protruding from the substrate 501.

It should be noted that the substrate is a silicon substrate 501. In other implementations, a material of the substrate may also be another material such as germanium, silicon-germanium, silicon carbide, gallium arsenide, indium-gallium or the like. The substrate may also be another type of substrate such as a silicon on insulator substrate, a germanium on insulator substrate or the like.

As an example, the bottom fin 502 and the substrate 501 are an integrated structure.

In some implementations, a channel protrusion 510 is formed on the base 500. The channel protrusion 510s one or more channel stacks 511 sequentially stacked along the longitudinal direction. Here, the longitudinal direction refers to the normal direction of the top surface of the substrate 501.

Accordingly, the channel protrusion 510 is located on the bottom fin 502.

The channel stack 511 provides a process basis for the subsequent formation of the channel layers 513 suspended at intervals.

Specifically, the channel layer 513 is used as a conductive channel of the gate-all-around transistor, and the sacrificial layer 512 is used for supporting the channel layer 513, thereby providing a process basis for the subsequent suspension of the channel layers 513 at intervals. The sacrificial layer 512 is also used for occupying a spatial position for the subsequent formation of the device gate structure.

A material of the channel layer 513 may be at least one of silicon, germanium, silicon-germanium, silicon carbide, gallium nitride, gallium arsenide or indium-gallium.

In some implementations, the material of the channel layer 513 is silicon, and a material of the sacrificial layer 512 is silicon-germanium. Since there is a high etch selectivity between silicon-germanium and silicon, in the subsequent process of removing the sacrificial layer 512, by setting the material of the sacrificial layer 512 as silicon-germanium and the material of the channel layer 513 as silicon, it is easy to effectively reduce the influence of the sacrificial layer 512 removal process on the channel layer 513, and the quality of the channel layer 513 is better accordingly, which thereby helps in improving the performance of the semiconductor device. In other implementations, the material of the channel layer may also be silicon-germanium, and the material of the sacrificial layer is silicon accordingly.

In some implementations, a first isolation layer 520 is formed on the substrate 501 on a side of the bottom fin 502. The first isolation layer 520 covers a side wall of the bottom fin 502.

The first isolation layer 520 is used for realizing electrical isolation between the adjacent bottom fins 502, and may further isolate the substrate 501 and the gate structure formed subsequently.

The first isolation layer 520 covers the side wall of the bottom fin 502, that is, the first isolation layer 520 exposes the channel stack 511, so that the channel stack 511 is used as an active fin, and the active fin covered by the gate structure formed subsequently is used for providing a conductive channel when the device works.

In some implementations, the first isolation layer 520 is a shallow trench isolation (STI).

A material of the first isolation layer 520 includes at least one of silicon oxide, silicon nitride or silicon oxynitride.

In some implementations, after providing the base 500 and before forming the gate structure spanning the channel stack 511, the method further includes: forming a first gate dielectric layer 531 covering a top and a side wall of the channel protrusion 510.

The first gate dielectric layer 531 is used for isolating the gate structure formed subsequently and the channel protrusion 510.

In some implementations, the first gate dielectric layer 531 is a gate oxide layer, and a material of the first gate dielectric layer 531 includes silicon oxide or nitrogen-doped silicon oxide.

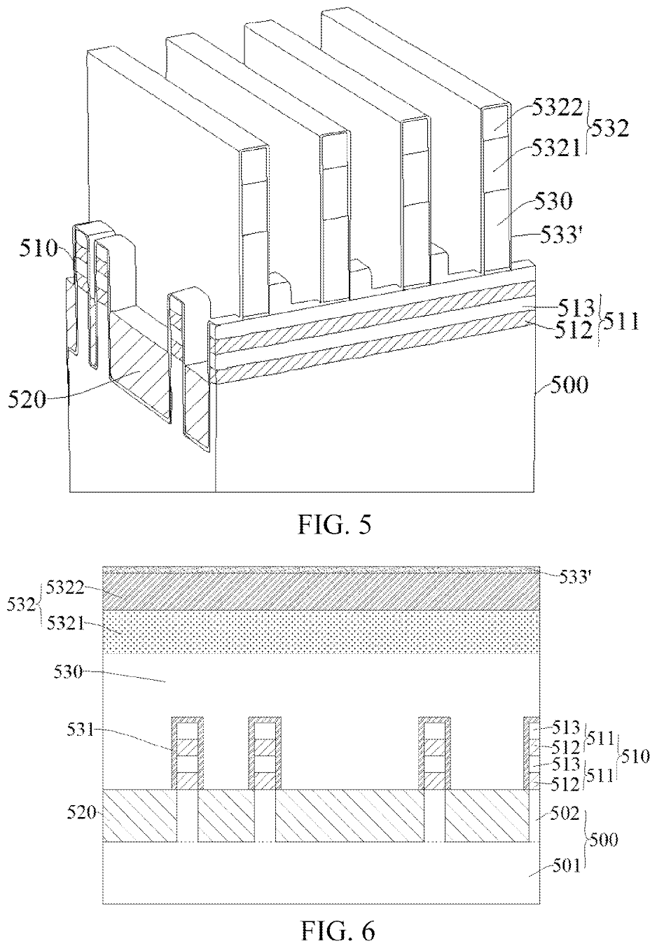

Referring to FIG. 5 to FIG. 7, a gate structure 530 spanning the channel stack 511 is formed. The gate structure 530 covers part of a top and part of a side wall of the channel stack 511.

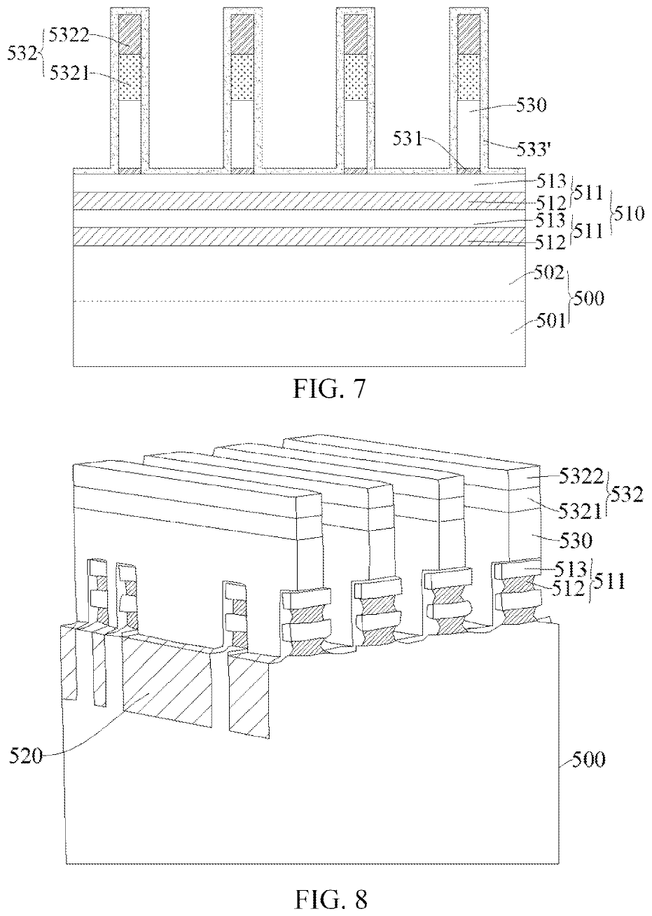

FIG. 5 is a three-dimensional view. FIG. 6 is a cross-sectional view of FIG. 5 at the gate structure 530 along an extending direction of the gate structure 530. FIG. 7 is a cross-sectional view of FIG. 5 at a position of the channel protrusion 510 along an extending direction of the channel protrusion 510, with the cross-sectional line near a middle position of the channel protrusion 510.

The channel stack 511 is used as an active fin, and the active fin covered by the gate structure 530 is used for providing a conductive channel when the device works.

The gate structure 530 is a dummy gate, used for reserving space for the device gate structure formed subsequently. A material of the dummy gate includes polysilicon or amorphous silicon.

In some implementations, a hard mask structure 532 is further formed on the top of the gate structure 530.

The hard mask structure 532 is used as an etching mask for forming the gate structure 530, and also used for protecting the top of the gate structure 530.

Specifically, the hard mask structure 532 includes a first hard mask layer 5321 covering the top of the gate structure 530, and a second hard mask layer 5322 covering the first hard mask layer 5321.

In some implementations, a material of the first hard mask layer 5321 includes silicon nitride, and a material of the second hard mask layer 5322 includes silicon oxide.

Referring to FIG. 5 to FIG. 11, in some implementations, after forming the gate structure 530 and before removing the channel stack 511 on the two sides of the gate structure 530, the method further includes: forming a spacer structure 533 on a side wall of the gate structure 530.

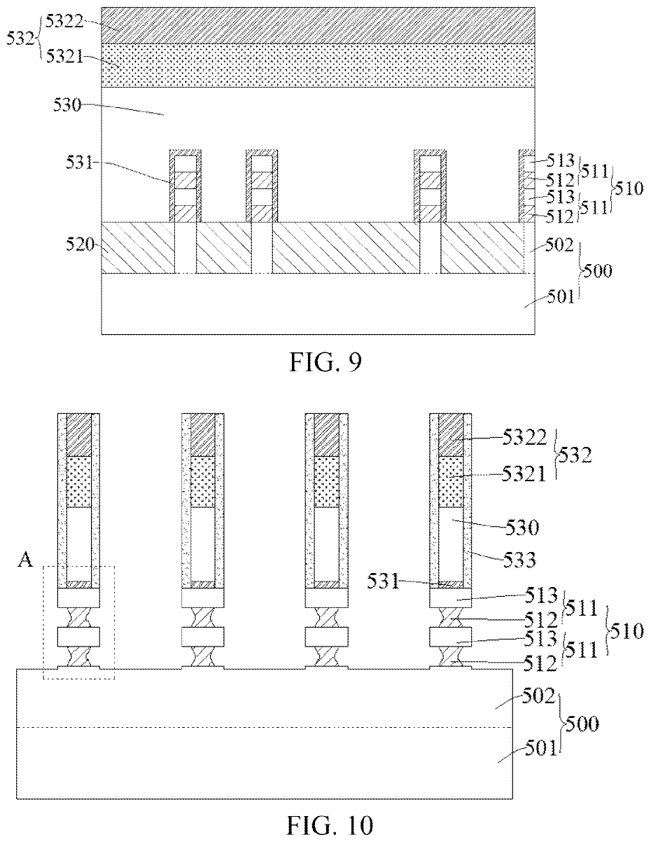

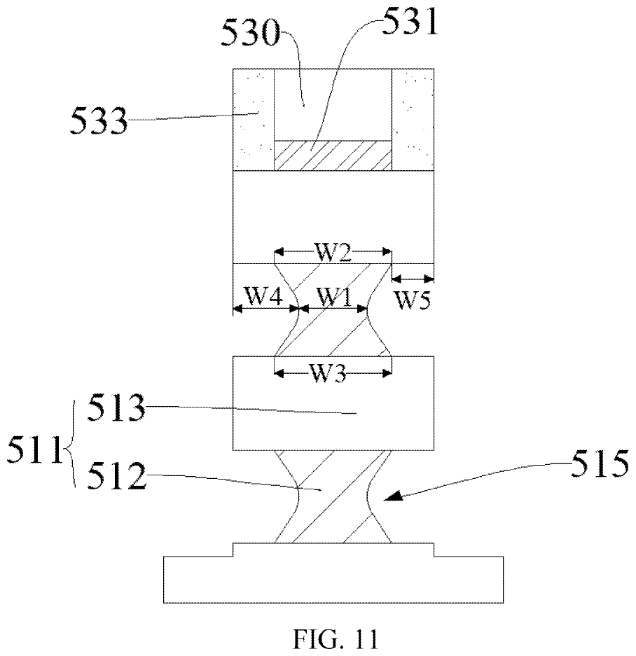

FIG. 8 is a three-dimensional view (for the convenience of showing the overall structure, the spacer structure 533 is not illustrated in FIG. 8). FIG. 9 is a cross-sectional view of FIG. 8 at the gate structure 530 along the extending direction of the gate structure 530. FIG. 10 is a cross-sectional view of FIG. 8 at the position of the channel protrusion 510 along the extending direction of the channel protrusion 510, with the cross-sectional line near the middle position of the channel protrusion 510. FIG. 11 is a partial enlarged view of A in FIG. 10.

The spacer structure 533 is used for protecting the side wall of the gate structure 530 during the forming process of the semiconductor structure.

Specifically, the step of forming the spacer structure 533 includes: as shown in FIG. 5 to FIG. 7, forming a gate spacer material layer 533′ above the top and on the side wall of the gate structure 530, on the top and the side wall of the channel protrusion 510 on the two sides of the 530, and on the first isolation layer 520; as shown in FIG. 8 to FIG. 11, removing the gate spacer material layer 533′ above the top of the gate structure 530, on the top of the channel protrusion 510 and on the first isolation layer 520, the remaining gate spacer material layer 533′ serving as the spacer structure 533 (as shown in FIG. 10 and FIG. 11).

It should be noted that the spacer structure 533 may be a single-layer structure or a laminate structure, and a material of the spacer structure 533 includes at least one of silicon oxide, silicon nitride, silicon carbide, silicon carbonitride, silicon oxycarbonitride, silicon oxynitride, boron nitride or boron carbonitride.

Referring to FIG. 8 to FIG. 11, the channel stack 511 on two sides of the gate structure 530 is removed.

The channel stack 511 on two sides of the gate structure 530 is removed, thereby providing space for the subsequent formation of the source/drain doped layer. Still referring to FIG. 8 to FIG. 11, after removing the channel stack 511 on the two sides of the gate structure 530 is removed, part of a width of the sacrificial layer 512 is laterally removed along a direction perpendicular to a side wall of the gate structure 530 to form an inner trench 515 between the channel layers 513 and/or between the channel layers 513 and the base 500.

The inner trench 515 provides a spatial position for the subsequent formation of the inner spacer.

As shown in FIG. 11, in some implementations, in the step of laterally removing part of the width of the sacrificial layer 512 along the direction perpendicular to the side wall of the gate structure 530 to form the inner trench 515 between the channel layers 513 and/or between the channel layers 513 and the base 500, the remaining sacrificial layer 512 between the inner trenches 515 has a smaller width W1 near the middle position than a top width W2 and a bottom width W3, so that the inner trench 515 has a larger lateral depth W4 near the middle position than a lateral depth W5 at a position near the channel layer 513.

The remaining sacrificial layer 512 between the inner trenches 515 has the smaller width W1 near the middle position than the top width W2 and the bottom width W3, that is, along the direction perpendicular to the side wall of the gate structure 530, the side wall of the remaining sacrificial layer 512 is recessed to the inside.

The lateral depth W4 of the inner trench 515 near the middle position is larger than the lateral depth W5 at the position near the channel layer 513, which, as compared with the solution in which the lateral depth W4 at the position near the channel layer 513 is equal to the lateral depth W5 near the middle position, increases the inner space of the inner trench near the middle position 515, making it easy to leave a gap between the inner spacer subsequently formed and the source/drain doped layer. Here, the lateral depth refers to the depth of the inner trench 515 along the direction perpendicular to the side wall of the gate structure 530. The middle position refers to the middle position of the sacrificial layer 512 along its height direction.

Specifically, in the step of forming the inner trench 515 between the channel layers 513 and/or between the channel layers 513 and the base 500, the side wall of the inner trench 515 facing the sacrificial layer 512 is 2-shaped or bowl-shaped. That is, the side wall of the inner trench has a corner angle facing the sacrificial layer 512, and the corner angle includes a sharp corner or a round corner.

The side wall of the inner trench 515 facing the sacrificial layer 512 is 2-shaped or bowl-shaped, which helps in reducing the difficulty of the process of forming the inner trench 515 having the lateral depth near the middle position larger than the lateral depth at the position near the channel layer 513, and is easy to achieve in the process.

It should be noted that a process of laterally removing part of the width of the sacrificial layer 512 includes one or two of a chemical vapor etching process and a plasma etching process.

In the etching process of laterally removing part of the width of the sacrificial layer 512, an etching rate near the middle position of the sacrificial layer 512 is usually larger than an etching rate near the channel layer 513, so that it is easy to make the inner trench 515 have the larger lateral depth near the middle position than the lateral depth at the position near the channel layer 513.

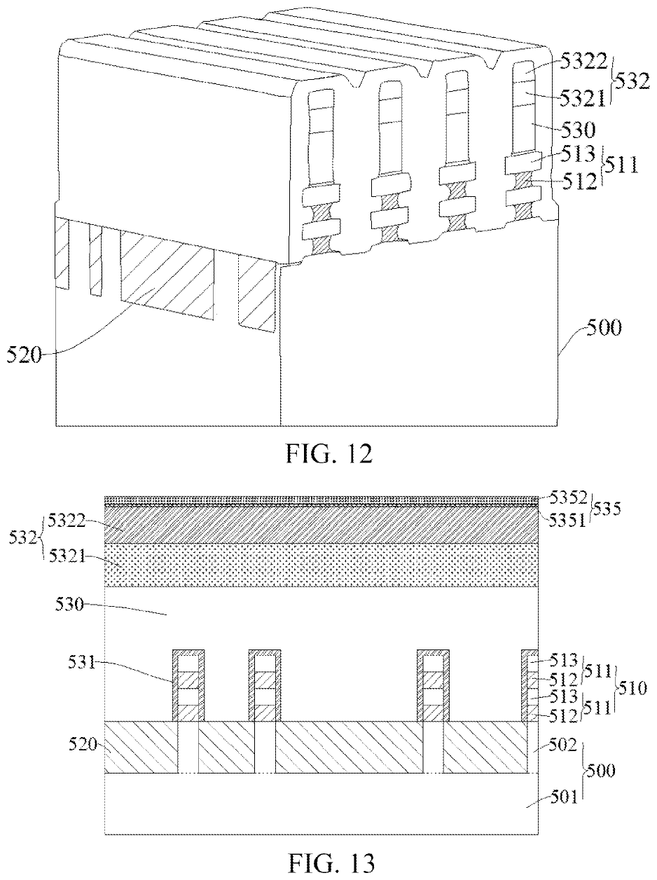

As an example, in the process of laterally removing part of the width of the sacrificial layer, an etch selectivity between the sacrificial layer 512 and the channel layer 513 is larger than 60, thereby reducing the probability of damage to the channel layer 513. Referring to FIG. 12 to FIG. 23, an inner spacer 534 is formed in the inner trench 515.

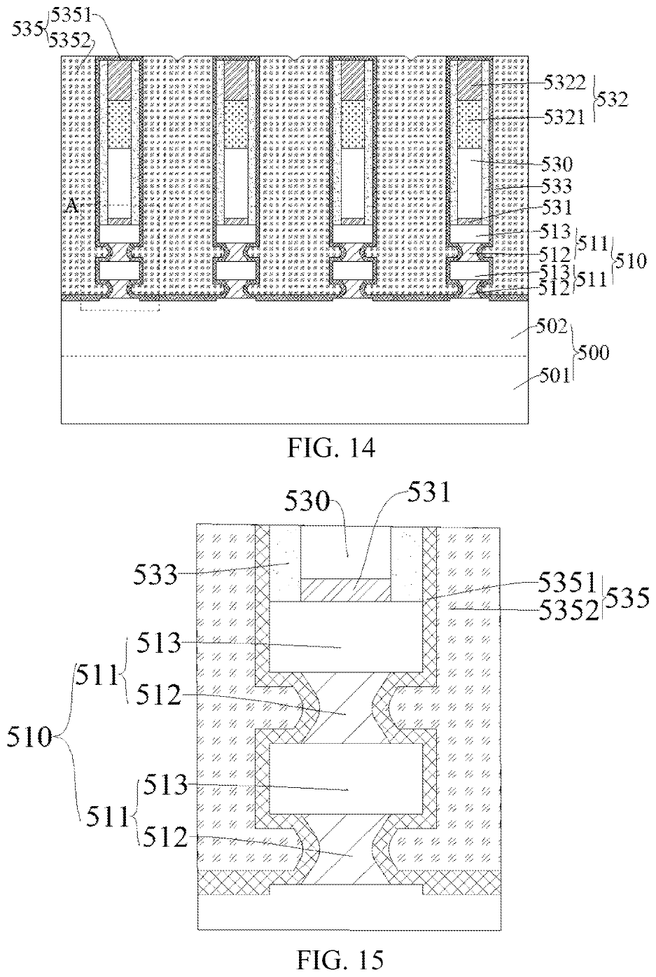

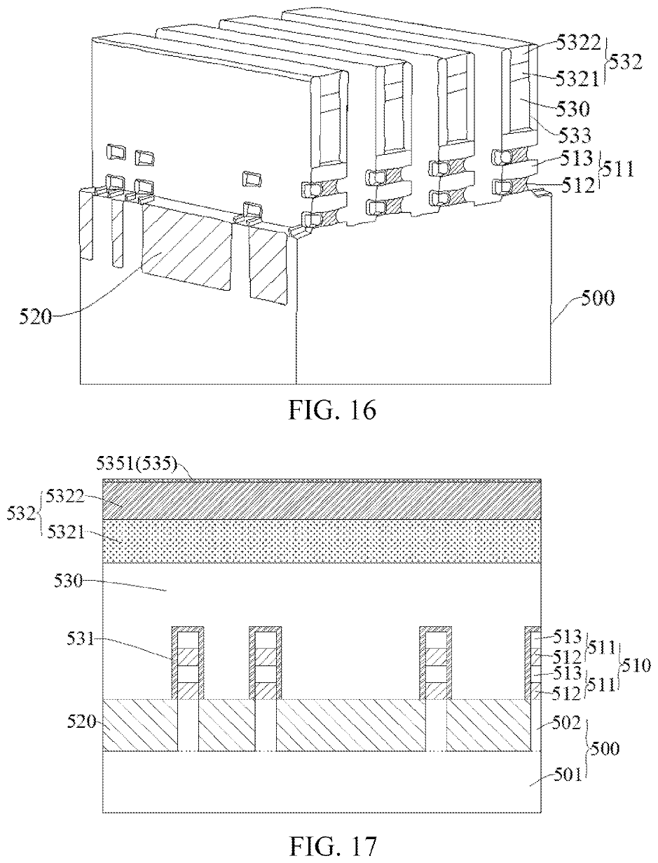

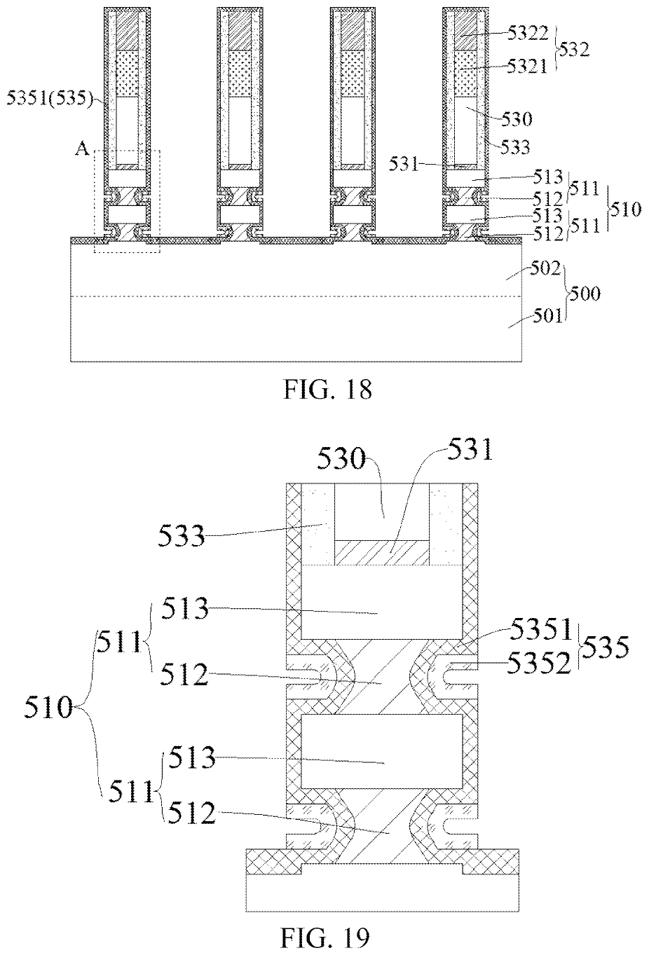

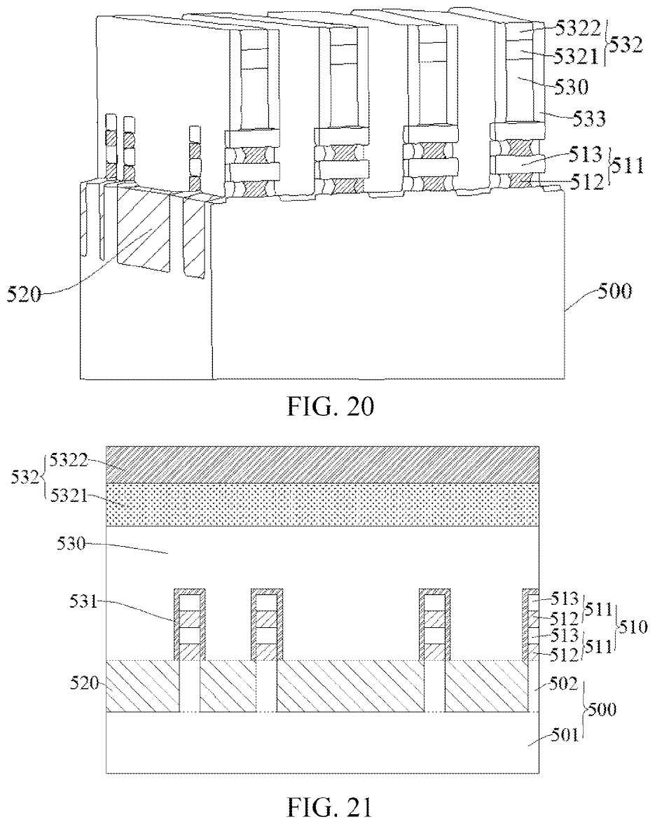

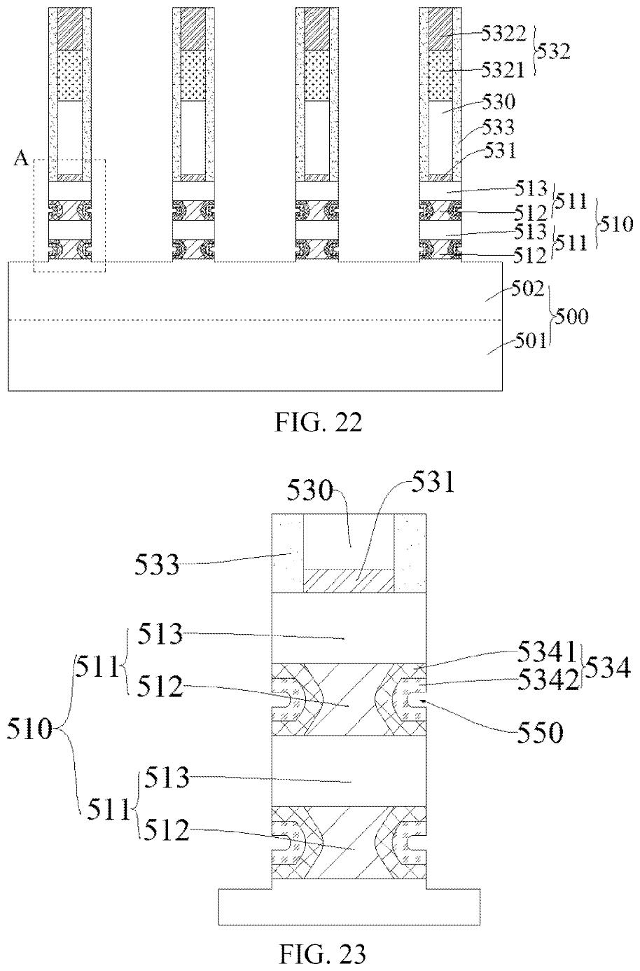

FIG. 12, FIG. 16 and FIG. 20 are three-dimensional views of different stages in the process of forming the inner spacer 534. For the convenience of showing the overall structure, the spacer structure 533 is not illustrated in FIG. 12. FIG. 13 is a cross-sectional view of FIG. 12 at the gate structure 530 along the extending direction of the gate structure 530. FIG. 14 is a cross-sectional view of FIG. 12 at the position of the channel protrusion 510 along the extending direction of the channel protrusion 510, with the cross-sectional line near the middle position of the channel protrusion 510. FIG. 15 is a partial enlarged view of A in FIG. 14. FIG. 17 is a cross-sectional view of FIG. 16 at the gate structure 530 along the extending direction of the gate structure 530. FIG. 18 is a cross-sectional view of FIG. 16 at the position of the channel protrusion 510 along the extending direction of the channel protrusion 510, with the cross-sectional line near the middle position of the channel protrusion 510. FIG. 19 is a partial enlarged view of A in FIG. 18. FIG. 21 is a cross-sectional view of FIG. 20 at the gate structure 530 along the extending direction of the gate structure 530. FIG. 22 is a cross-sectional view of FIG. 20 at the position of the channel protrusion 510 along the extending direction of the channel protrusion 510, with the cross-sectional line near the middle position of the channel protrusion 510. FIG. 23 is a partial enlarged view of A in FIG. 22.

The inner spacer 534 is used for realizing isolation between the source/drain doped layer subsequently formed and the inner gate structure.

In some implementations, the inner spacer 534 fills part of space in the inner trench 515.

Specifically, a material of the inner spacer material layer 535 includes at least one of silicon oxide, silicon nitride, silicon oxynitride, silicon oxycarbide or silicon oxycarbonitride.

Specifically, the step of forming the inner spacer 534 in the inner trench 515 includes: forming an inner spacer material layer 535 covering the side wall and the top of the gate structure 530, the ends of the channel stack 511 and the base 500 on the sides of the gate structure 530, the inner spacer material layer 535 further filling the inner trench 515; and removing the inner spacer material layer 535 on the side wall and the top of the gate structure 530, the ends of the channel stack 511 and the base 500 on the sides of the gate structure 530, and removing part of the inner spacer material layer 535 located in the inner trench 515, such that the inner spacer material layer 535 fills part of space in the inner trench 515 and the remaining inner spacer material layer 535 serves as the inner spacer 534.

First, the inner spacer material layer 535 covering the side wall and the top of the gate structure 530, the ends of the channel stack 511 and the base on the sides of the gate structure 530 is removed, and the inner spacer material layer 535 further fills the inner trench 515, thereby ensuring the covering effect of the inner spacer material layer 535 on the inner wall of the inner trench 515. Then, the inner spacer material layer 535 on the side wall and the top of the gate structure 530, the ends of the channel stack 511 and the base 500 on the sides of the gate structure 530 is removed, and part of the inner spacer material layer 535 located in the inner trench 515 is removed, which helps in reducing the difficulty of the process of forming the inner spacer 534 in the inner trench 515, and thereby helps in improving the quality of the formed inner spacer 534. Moreover, part of the inner spacer material layer 535 located in the inner trench 515 is removed, so that the inner spacer material layer 535 fills part of the space in the inner trench 515, that is, the inner spacer 534 only fills part of the space in the inner trench 515, thereby providing the space required for forming the gap, making it easy to form the gap between the inner spacer 534 and the source/drain doped layer formed subsequently, and reducing the difficulty of the process of forming the gap.

In some implementations, after the inner spacer material layer 535 is formed, the inner spacer material layer 535 fills the inner trench 515. This helps in improving the uniformity of the covering effect of the inner spacer material layer 535 on the inner trench, and accordingly, improves the uniformity of the covering effect of the remaining inner spacer material layer 535 (i.e., inner spacer 534) on the inner wall of the inner trench 515 and the completeness of the inner spacer 534 after part of the inner spacer material layer 535 is removed subsequently, thereby reducing the probability of damage to the source/drain doped layer.

Specifically, after the sacrificial layer 512 is removed subsequently, the inner gate structure is formed at the position of the sacrificial layer 512, so that the covering power of the inner spacer 534 on the inner wall of the inner trench 515 is improved and the probability of exposing the side wall of the sacrificial layer 512 by the inner spacer 534 is reduced, thereby reducing the probability of damage to the source/drain doped layer caused during the removal of the sacrificial layer 512 via the notch in the inner spacer 534.

In some implementations, the inner spacer 534 conformally covers the inner wall of the inner trench 515.

Specifically, in the step of removing part of the inner spacer material layer 535 located in the inner trench 515, the remaining inner spacer material layer 535 is made conformally cover the inner wall of the inner trench 515.

The remaining inner spacer material layer 535 conformally covers the inner wall of the inner trench 515, which helps in increasing the space in the inner trench 515 that is not filled by the inner spacer 534 and further helps in increasing the volume of the gap between the inner spacer 534 and the source/drain doped layer formed subsequently, making a better effect of reducing the parasitic capacitance of the semiconductor device formed subsequently.

Moreover, this helps in improving the covering power of the inner spacer 534 on the surface of the channel layer 513 in the inner trench 515, thereby reducing the probability of growth of the source/drain doped layer 540 on the basis of the surface of the channel layer 513 in the inner trench 515, and further reducing the probability of the source/drain doped layer 540 filling the inside of the inner trench 515. Accordingly, the source/drain doped layer can easily seal the inner trench 515 at the opening of the inner trench 515 so as to form the gap with larger space.

In addition, this also helps in improving the covering power of the remaining inner spacer material layer 535 on the inner wall of the inner trench, and accordingly improves the completeness of the inner spacer 534, thereby reducing the probability of damage to the source/drain doped layer.

It should be noted that along the direction perpendicular to the side wall of the gate structure 530, the sacrificial layer 512 between the inner trenches 515 has a smaller width W1 near the middle position than a top width W2 and a bottom width W3, so that the inner trench has a larger lateral depth W4 near the middle position than a lateral depth W5 at the position near the channel layer 513. Therefore, based on the size characteristics or morphology characteristics of the inner trench 515, the inner spacer 534 can easily fill part of the space in the inner trench 515.

It should also be noted that a process of forming the inner spacer material layer 535 includes an atomic layer deposition process. The atomic layer deposition process includes multiple atomic layer deposition cycles. The atomic layer deposition process has good gap filling performance and step coverage, and accordingly improves the gap filling capacity of the inner spacer material layer 535 and the covering power of the inner spacer material layer on the inner wall of the inner trench 515.

In some implementations, the step of forming the inner spacer material layer 535 includes: forming a first inner spacer material layer 5351 on the side wall and the top of the gate structure 530, the ends of the channel stack 511 and the base 500 on the sides of the gate structure 530, the first inner spacer material layer 5351 further covering an inner wall of the inner trench 515; and forming a second inner spacer material layer 5352 covering the first inner spacer material layer 5351, the second inner spacer material layer 5352 further filling the inner trench 515, the first inner spacer material layer 5351 and the second inner spacer material layer 5352 forming the inner spacer material layer 535, and there being an etch selectivity between the second inner spacer material layer 5352 and the first inner spacer material layer 5351.

Accordingly, the step of removing the inner spacer material layer 535 on the side wall and the top of the gate structure 530, the ends of the channel stack 511 and the base 500 on the sides of the gate structure 530, and removing part of the inner spacer material layer 535 located in the inner trench 515 includes: removing the second inner spacer material layer 5352 on the side wall and the top of the gate structure 530, the ends of the channel stack 511 and the base 500 on the sides of the gate structure 530, and removing part of the second inner spacer material layer 5352 located in the inner trench 515, such that the second inner spacer material layer 5352 fills part of the space in the inner trench 515; and removing, after the second inner spacer material layer 5352 fills part of the space in the inner trench 515, the first inner spacer material layer 5351 on the side wall and the top of the gate structure 530, the ends of the channel stack 511 and the base 500 on the sides of the gate structure 530, the remaining first inner spacer material layer 5351 and the second inner spacer material layer 5352 forming the inner spacer 534.

There is an etch selectivity between the second inner spacer material layer 5352 and the first inner spacer material layer 5351, so that in the process of removing part of the second inner spacer material layer 5352 located in the inner trench 515, the first inner spacer material layer 5351 may serve as a barrier layer, which reduces the probability of damage to other components.

Specifically, in the process of forming the inner spacer 534, the inner spacer material layer 535 used for forming the inner spacer 534 also covers the side wall and the top of the gate structure 530, the ends of the channel layer 511 and the base 500 on the sides of the gate structure 530. In this case, when removing a part of the second inner spacer material layer 5352, by using the first inner spacer material layer 5351 as the barrier layer, the second inner spacer material layer 5352 on the side wall and the top of the gate structure 530, the ends of the channel layer 511 and the base 500 on the sides of the gate structure 530 may be removed, and part of the second inner spacer material layer 5352 located in the inner trench 515 may be removed, thereby reducing the probability of damage to other components (e.g., the spacer structure 533, the gate structure 530, the channel layer 511 or the base 500).

It should be noted that a thickness of the first inner spacer material layer 5351 should not be too large or too small. If the thickness of the first inner spacer material layer 5351 is too large, the difficulty in removing the first inner spacer material layer 5351 may be increased, and accordingly, the probability of damage to other components (e.g., the spacer structure 533, the gate structure 530, the channel stack 511 or the base 500) in the process of removing the first inner spacer material layer 5351 may also be increased. Moreover, since the first inner spacer material layer 5351 further covers the inner wall of the inner trench 515, if the thickness of the first inner spacer material layer 5351 is too large, the first inner spacer material layer 5351 may easily occupy too much space in the inner trench 515, and accordingly, the inner spacer material layer 535 may fill too much space in the inner trench 515, making the volume of the gap between the source/drain doped layer formed subsequently and the inner spacer 534 too small. If the thickness of the first inner spacer material layer 5351 is too small, the first inner spacer material layer 5351 may be ineffective as the barrier layer, and accordingly, may be ineffective in reducing damage to other components. Therefore, in the step of forming the first inner spacer material layer 5351 on the side wall and the top of the gate structure 530, the ends of the channel stack 511 and the base 500 on the sides of the gate structure 530, the thickness of the first inner spacer material layer 5351 is 0.5 nm to 50 nm.

In some implementations, after the second inner spacer material layer 5352 is formed, the second inner spacer material layer 5352 fills the remaining space in the inner trench 515, which helps in improving the uniformity of the covering effect of the second inner spacer material layer 5352 on the inner trench 515. Accordingly, after the second inner spacer material layer 5352 on the side wall and the top of the gate structure 530, the ends of the channel stack 511 and the base 500 on the sides of the gate structure 530 is removed, and part of the second inner spacer material layer 5352 located in the inner trench 515 is removed such that the second inner spacer material layer 5352 fills part of the space in the inner trench 515, the remaining second inner spacer material layer 5352 can well cover the first inner spacer material layer 5351 in the inner trench 515 and protect the first inner spacer material layer 5351 in the inner trench 515. Thus, when the first inner spacer material layer 5351 on the side wall and the top of the gate structure 530, the ends of the channel stack 511 and the base 500 on the sides of the gate structure 530 is removed, the completeness of the first inner spacer material layer 5351 in the inner trench 515 can be ensured, which reduces the probability of exposing the sacrificial layer 512 between the inner trenches 515.

Specifically, after the source/drain doped layer is formed subsequently, the gate structure 530 and the sacrificial layer 512 are further removed, so that the probability of exposing the sacrificial layer 512 between the inner trenches 515 is reduced, thereby reducing the probability of damage to the source/drain doped layer caused during the removal of the sacrificial layer 512 via the notch in the inner spacer 534.

It should be noted that as shown in FIG. 12 and FIG. 14, this implementation is described in an example where the second inner spacer material layer 5352 further fills space between the adjacent gate structures 530. It can be understood that in other implementations, the second inner spacer material layer may also not fully fill the space between the adjacent gate structures.

In some implementations, a process of removing the second inner spacer material layer 5352 on the side wall and the top of the gate structure 530, the ends of the channel stack 511 and the base 500 on the sides of the gate structure 530 includes an anisotropic plasma etching process, and a process of removing part of the second inner spacer material layer located in the inner trench includes an isotropic plasma etching process.

It should be noted that the plasma etching process has a higher etch selectivity, which helps in reducing the influence of the process of etching the second inner spacer material layer 5352 on other layers.

Specifically, the second inner spacer material layer 5352 on the side wall and the top of the gate structure 530, the ends of the channel stack 511 and the base 500 on the sides of the gate structure 530 is removed by the anisotropic plasma etching process, and then, part of the second inner spacer material layer 5352 located in the inner trench 515 is removed by the isotropic plasma etching process.

First, the second inner spacer material layer 5352 is etched by the anisotropic etching process to remove the second inner spacer material layer 5352 on the side wall and the top of the gate structure 530, the ends of the channel stack 511 and the base 500 on the sides of the gate structure 530, thereby reducing damage to the second inner spacer material layer 5352 in the inner trench 515, and providing a good process basis for the subsequent lateral etching of the second inner spacer material layer 5352.

Then, the second inner spacer material layer 5352 is etched by the isotropic etching process, so that the second inner spacer material layer can be etched along the lateral direction, thereby removing part of the inner spacer material layer 535 located in the inner trench 515.

As an example, after part of the second inner spacer material layer 5352 located in the inner trench 515 is removed, the thickness of the second inner spacer material layer 5352 near the outer side of the inner trench 515 is smaller than the thickness of the second inner spacer material layer 5352 on the inner side of the inner trench, that is, the thickness of the second inner spacer material layer 5352 gradually becomes smaller as it is away from the sacrificial layer 512.

In some implementations, a process of removing the first inner spacer material layer 5351 on the side wall and the top of the gate structure 530, the ends of the channel stack 511 and the base 500 on the sides of the gate structure 530 includes one or two of a wet etching process or a chemical vapor etching process.

The wet etching process and the chemical vapor etching process can easily realize a higher etch selectivity between the etched object and other layers, thereby reducing the probability of damage to other layers. Moreover, the wet etching process and the chemical vapor etching process have smaller process difficulty.

In some implementations, in the process of removing part of the second inner spacer material layer 5352 located in the inner trench 515, the etch selectivity between the second inner spacer material layer 5352 and the first inner spacer material layer 5351 is larger than 80.

The etch selectivity between the second inner spacer material layer 5352 and the first inner spacer material layer 5351 is larger than 80, so that the first inner spacer material layer 5351 is effective as the barrier layer in the process of removing part of the second inner spacer material layer 5352 located in the inner trench 515, and accordingly, is effective in avoiding damage to other components.

In some implementations, in the process of removing the first inner spacer material layer 5351 on the side wall and the top of the gate structure 530, the ends of the channel stack 511 and the base 500 on the sides of the gate structure 530, the etch selectivity between the first inner spacer material layer 5351 and the second inner spacer material layer 5352 is larger than 100.

The etch selectivity between the first inner spacer material layer 5351 and the second inner spacer material layer 5352 is larger than 100, which helps in reducing the probability of removal of the remaining second inner spacer material layer 5352 in the inner trench 515 in the process of removing the first inner spacer material layer 5351 on the side wall and the top of the gate structure 530, the ends of the channel stack 511 and the base 500 on the sides of the gate structure 530, thereby improving the completeness of the remaining second inner spacer material layer 5352 and accordingly improving the protection of the remaining second inner spacer material layer 5352 on the first inner spacer material layer 5351 in the inner trench 515.

In some implementations, a material of the inner spacer material layer 535 includes at least one of silicon oxide, silicon nitride, silicon oxynitride, silicon oxycarbide or silicon oxycarbonitride.

As an example, a material of the first inner spacer material layer 5351 is silicon oxide, and a material of the second inner spacer material layer 5352 is silicon nitride. There is a large etch selectivity between silicon nitride and silicon oxide. Moreover, when the material of the first inner spacer material layer 5351 is silicon oxide, it is easy to remove part of the first inner spacer material layer 5351 before forming the source/drain doped layer.

It should be noted that as shown in FIG. 20 to FIG. 23, before forming the source/drain doped layer, the method further includes: precleaning the base 500 on the two sides of the gate structure 530 and the ends of the channel stack 511, and during the precleaning process, removing the first inner spacer material layer 5351 on the side wall and the top of the gate structure 530, the ends of the channel stack 511 and the base 500 on the sides of the gate structure 530.

The first inner spacer material layer 5351 on the side wall and the top of the gate structure 530, the ends of the channel stack 511 and the base 500 on the sides of the gate structure 530 is removed to expose the ends of the channel stack 511 and the base 500 on the sides of the gate structure 530, thereby facilitating the subsequent growth process of the source/drain doped layer.

The base 500 on the two sides of the gate structure 530 and the ends of the channel stack 511 are precleaned, which helps in providing a good process basis for the subsequent formation of the source/drain doped layer connected to the two ends of the channel layer 513 on the base 500 on the two sides of the gate structure 530, and thereby helps in improving the quality of the formed source/drain doped layer. Moreover, in the precleaning process, the first inner spacer material layer 5351 on the side wall and the top of the gate structure 530, the ends of the channel stack 511 and the base 500 on the sides of the gate structure 530 is removed, which facilitates the combination with the existing process, simplifies the process steps and saves the process cost.

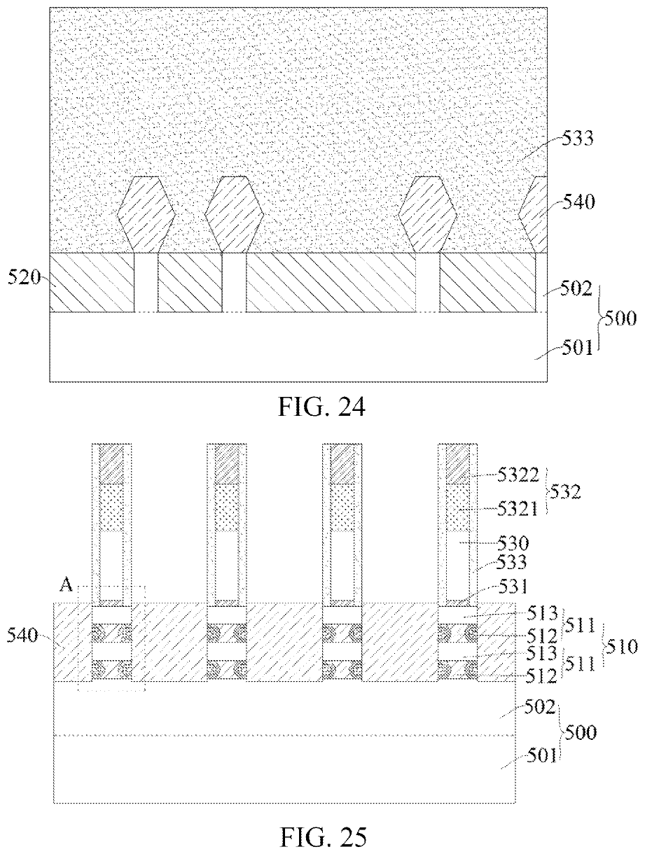

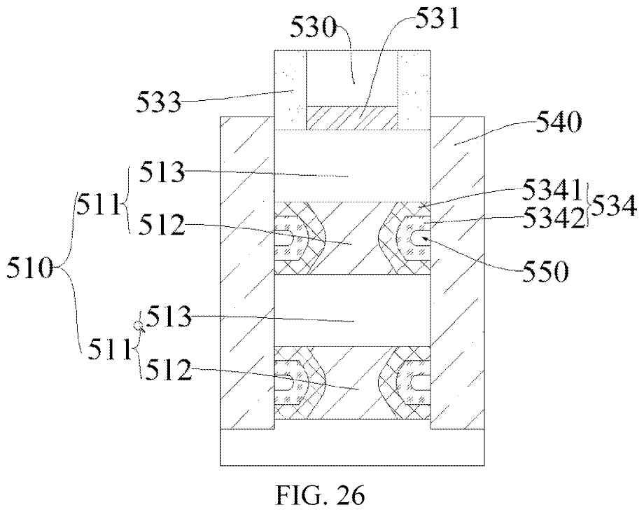

Referring to FIG. 24 to FIG. 26, FIG. 24 is a cross-sectional view at the position of the side of the gate structure 530 along the extending direction of the gate structure 530. FIG. 25 is a cross-sectional view at the position of the channel protrusion 510 along the extending direction of the channel protrusion 510, with the cross-sectional line near the middle position of the channel protrusion 510. FIG. 26 is a partial enlarged view of A in FIG. 25. A source/drain doped layer 540 connected to two ends of the channel layer is formed on the base 500 on the two sides of the gate structure 530. The source/drain doped layer 540 and the inner spacer 534 have a gap 550 therebetween, and the gap 550 is used as an air spacer.

The source/drain doped layer 540 is used as a source or drain of the gate-all-around transistor. When the gate-all-around transistor works, the source/drain doped layer 540 is used for providing a carrier source.

The inner trench 515 is formed between the channel layers 513, and/or, between the channel layers 513 and the base 500; the inner spacer 534 is formed in the inner trench 515; and the source/drain doped layer 540 connected to the two ends of the channel layer 513 is formed on the base 500 on the two sides of the gate structure 530. The source/drain doped layer 540 and the inner spacer 534 have the gap 550 therebetween, and the gap 550 is used as the air spacer. Since the air has a smaller dielectric constant than the dielectric material, the parasitic capacitance of the semiconductor device formed subsequently is reduced, thereby improving the AC performance of the semiconductor device formed subsequently and further improving the performance of the semiconductor structure.

Moreover, since the parasitic capacitance of the semiconductor device mainly comes from the parasitic capacitance generated between the device gate structure and the source/drain doped layer 540, the air spacer is formed between the source/drain doped layer 540 and the inner spacer 534, which is more effective in reducing the parasitic capacitance of the semiconductor device.

It should be noted that the specific shape of the gap 550 is determined by the process and process parameters for forming the source/drain doped layer 540, and the shape of the inner spacer 534 occupying the space in the inner trench 515. As an example, the shape of the gap 550 includes at least one of crescent, ellipsoidal, hemispherical or irregular shapes.

In some implementations, part of the inner spacer material layer 535 located in the inner trench 515 is removed, such that the inner spacer material layer 535 fills part of the space of the inner trench 515 and the remaining inner spacer material layer 535 serves as the inner spacer 534. Accordingly, in the step of forming the source/drain doped layer 540, the source/drain doped layer 540 seals the inner trench 515 and forms the gap 550 with the inner spacer 534.

In some implementations, after forming the source/drain doped layer, the forming method further includes: forming an interlayer dielectric layer (not shown) on the first isolation layer 520 on the side of the gate structure 530, the interlayer dielectric layer covering the source/drain doped layer 540; removing the hard mask structure 532; after removing the hard mask structure 532, removing the gate structure 530 to form a gate opening (not shown); removing the sacrificial layer 512 through the gate opening to form a through slot (not shown), the through slot communicating with the gate opening; and forming the device gate structure (not shown) in the through slot and the gate opening, the device gate structure spanning the channel protrusion 510 and surrounding and covering the channel layer 513, and the device gate structure located between the channel layers 513 and between the channel layer 513 and the bottom fin 502 serving as an inner gate structure (not shown).

In some implementations, after removing the gate structure 530 and before forming the device gate structure, the first gate dielectric layer 531 is further removed. In other implementations, after removing the gate structure, the first gate dielectric layer may also be reserved.

As an example, the device gate structure is a metal gate structure, and the device gate structure includes a second gate dielectric layer and a gate electrode layer covering the second gate dielectric layer.

A material of the second gate dielectric layer includes at least one of HfO₂, ZrO₂, HfSiO, HfSiON, HfTaO, HfTIO, HfZrO, Al₂O₃, SiO₂ or La₂O₃. In some implementations, the second gate dielectric layer includes a high k gate dielectric layer, and a material of the high k gate dielectric layer is a high k dielectric material. The high k dielectric material refers to a dielectric material having a relative dielectric constant greater than a relative dielectric constant of silicon oxide. As an example, the material of the high k gate dielectric layer is HfO₂.

A material of the gate electrode layer includes at least one of TiN, TaN, Ta, Ti, TiAl, W, Al, TiSiN and TiAIC. The gate electrode layer includes a work function layer and an electrode layer covering the work function layer, and may only include the work function layer.

It should be noted that the semiconductor structure of this implementation may be formed by forms of the method described in the foregoing implementation or by other forming methods.

Although embodiments and implementations of the present disclosure have been described above, the present disclosure is not limited thereto. Any person skilled in the art can make various changes and modifications without departing from the spirit and scope of the present disclosure, so the scope of protection of the disclosure shall be subject to the scope defined by the claims.

What is claimed is:

1. A semiconductor structure, comprising:
a base;
a channel protrusion structure, suspended on the base, the channel protrusion structure comprising one or more channel layers arranged at intervals along a longitudinal direction;
a gate structure, spanning the channel protrusion structure and covering part of a top and part of a side wall of the channel protrusion structure, the gate structure further surrounding and covering the one or more channel layers, the gate structure located between the adjacent channel layers in the longitudinal direction and between the adjacent channel layers and the base serving as an inner gate structure, and at least one of the inner gate structure and the adjacent channel layers or the inner gate structure, the adjacent channel layers and the base forming an inner trench;
an inner spacer, located in the inner trench; and
a source/drain doped layer, located on the base on two sides of the gate structure and connected to two ends of the channel layer, the source/drain doped layer and the inner spacer having a gap therebetween, and the gap being used as an air spacer.

2. The semiconductor structure according to claim 1, wherein:
the inner spacer fills part of space in the inner trench; and
the source/drain doped layer seals the inner trench and forms the gap with the inner spacer.

3. The semiconductor structure according to claim 2, wherein the inner spacer conformally covers an inner wall of the inner trench.

4. The semiconductor structure according to claim 1, wherein along a direction perpendicular to a side wall of the inner gate structure, the inner gate structure between the inner trenches has a smaller width near a middle position than a top width and a bottom width, so that the inner trench has a larger lateral depth near the middle position than a lateral depth at a position near the channel layer.

5. The semiconductor structure according to claim 4, wherein a side wall of the inner trench facing the inner gate structure is Σ-shaped or bowl-shaped.

6. The semiconductor structure according to claim 1, wherein the inner spacer comprises a first inner spacer covering the inner wall of the inner trench, and a second inner spacer covering the first inner spacer, and there is an etch selectivity between the second inner spacer and the first inner spacer.

7. The semiconductor structure according to claim 6, wherein a thickness of the first inner spacer is 0.5 nm to 50 nm.

8. The semiconductor structure according to claim 1, wherein a material of the inner spacer comprises at least one of silicon oxide, silicon nitride, silicon oxynitride, silicon oxycarbide or silicon oxycarbonitride.

9. The semiconductor structure according to claim 1, wherein a shape of the gap comprises at least one of crescent, ellipsoidal, hemispherical or irregular shapes.

10. The semiconductor structure according to claim 1, wherein:
the base comprises a substrate and a bottom fin protruding from the substrate;
the channel protrusion structure is suspended on the bottom fin; and
the semiconductor structure further comprises: a first isolation layer, located on the substrate on a side of the bottom fin, the first isolation layer covering a side wall of the bottom fin.

11. A forming method of a semiconductor structure, comprising:
providing a base, one or more channel stacks sequentially stacked along a longitudinal direction being formed on the base, where each channel stack comprises a sacrificial layer and a channel layer located on the sacrificial layer;
forming a gate structure spanning the one or more channel stacks, the gate structure covering part of a top and part of a side wall of the one or more channel stacks;
removing the channel stack on two sides of the gate structure;
laterally removing, after removing the channel stack on the two sides of the gate structure, part of a width of the sacrificial layer along a direction perpendicular to a side wall of the gate structure to form an inner trench between the channel layers and/or between the channel layers and the base;
forming an inner spacer in the inner trench; and
forming a source/drain doped layer connected to two ends of the channel layer on the base on the two sides of the gate structure, the source/drain doped layer and the inner spacer having a gap therebetween, and the gap being used as an air spacer.

12. The forming method of a semiconductor structure according to claim 11, wherein the step of forming the inner spacer in the inner trench comprises:
forming an inner spacer material layer covering the side wall and the top of the gate structure, the ends of the channel stack and the base on the sides of the gate structure, the inner spacer material layer further filling the inner trench; and
removing the inner spacer material layer on the side wall and the top of the gate structure, the ends of the channel stack and the base on the sides of the gate structure, and removing part of the inner spacer material layer located in the inner trench, such that the inner spacer material layer fills part of space in the inner trench and the remaining inner spacer material layer serves as the inner spacer; and
in the step of forming the source/drain doped layer, the source/drain doped layer seals the inner trench and forms the gap with the inner spacer.

13. The forming method of a semiconductor structure according to claim 12, wherein a process of forming the inner spacer material layer comprises an atomic layer deposition process.

14. The forming method of a semiconductor structure according to claim 12, wherein in the step of removing part of the inner spacer material layer located in the inner trench, the inner spacer material layer conformally covers an inner wall of the inner trench.

15. The forming method of a semiconductor structure according to claim 12, wherein:
the step of forming the inner spacer material layer comprises:
forming a first inner spacer material layer on the side wall and the top of the gate structure, the ends of the channel stack and the base on the sides of the gate structure, the first inner spacer material layer further covering an inner wall of the inner trench; and
forming a second inner spacer material layer covering the first inner spacer material layer, the second inner spacer material layer further filling the inner trench, the first inner spacer material layer and the second inner spacer material layer forming the inner spacer material layer, and there being an etch selectivity between the second inner spacer material layer and the first inner spacer material layer; and
the step of removing the inner spacer material layer on the side wall and the top of the gate structure, the ends of the channel stack and the base on the sides of the gate structure, and removing part of the inner spacer material layer located in the inner trench comprises:
removing the second inner spacer material layer on the side wall and the top of the gate structure, the ends of the channel stack and the base on the sides of the gate structure, and removing part of the second inner spacer material layer located in the inner trench, such that the second inner spacer material layer fills part of the space in the inner trench; and
removing, after the second inner spacer material layer fills part of the space in the inner trench, the first inner spacer material layer on the side wall and the top of the gate structure, the ends of the channel stack and the base on the sides of the gate structure, the remaining first inner spacer material layer and the second inner spacer material layer forming the inner spacer.

16. The forming method of a semiconductor structure according to claim 15, wherein before forming the source/drain doped layer, the method further comprises: precleaning the base on the two sides of the gate structure and the ends of the channel stack, and during the precleaning process, removing the first inner spacer material layer on the side wall and the top of the gate structure, the ends of the channel stack and the base on the sides of the gate structure.

17. The forming method of a semiconductor structure according to claim 15, wherein:
a process of removing the second inner spacer material layer on the side wall and the top of the gate structure, the ends of the channel stack and the base on the sides of the gate structure comprises an anisotropic plasma etching process, and a process of removing part of the second inner spacer material layer located in the inner trench comprises an isotropic plasma etching process; and
a process of removing the first inner spacer material layer on the side wall and the top of the gate structure, the ends of the channel stack and the base on the sides of the gate structure comprises one or two of a wet etching process or a chemical vapor etching process.

18. The forming method of a semiconductor structure according to claim 15, wherein:
in the process of removing part of the second inner spacer material layer located in the inner trench, the etch selectivity between the second inner spacer material layer and the first inner spacer material layer is larger than 80; and
in the process of removing the first inner spacer material layer on the side wall and the top of the gate structure, the ends of the channel stack and the base on the sides of the gate structure, the etch selectivity between the first inner spacer material layer and the second inner spacer material layer is larger than 100.

19. The forming method of a semiconductor structure according to claim 11, wherein in the step of laterally removing part of the width of the sacrificial layer along the direction perpendicular to the side wall of the gate structure to form the inner trench between at least one of the channel layers or the channel layers and the base, the remaining sacrificial layer between the inner trenches has a smaller width near a middle position than a top width and a bottom width, so that the inner trench has a larger lateral depth near the middle position than a lateral depth at a position near the channel layer.

20. The forming method of a semiconductor structure according to claim 19, wherein a process of laterally removing part of the width of the sacrificial layer comprises: one or two of a chemical vapor etching process and a plasma etching process.
